(19) United States
(12) Patent Application Publication
(10) Pub. No.: US 2024/0178048 A1
(43) Pub. Date: May 30, 2024

(54) APPARATUS FOR MANUFACTURING SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Yasushi TAKAKI, Tokyo (JP); Kinya YAMASHITA, Tokyo (JP); Masaki UENO, Tokyo (JP)

(73) Assignee: Mitsubishi Electric Corporation, Tokyo (JP)

(21) Appl. No.: 18/451,799

(22) Filed: Aug. 17, 2023

(30) Foreign Application Priority Data
Nov. 29, 2022 (JP) 2022-190319

(51) Int. Cl. H01L 21/687; H01L 21/683; H01L 21/78

(52) U.S. Cl. CPC H01L 21/6875; H01L 21/6836; H01L 21/6838; H01L 21/68742; H01L 21/78

(57) ABSTRACT

An apparatus for manufacturing semiconductor device includes a pickup apparatus. The pickup apparatus includes: a stage including a plurality of protruding portions disposed so as to face a back surface of a dicing sheet to which a semiconductor chip is attached; and a suction unit configured to vacuum-suck a space between an outer frame, the dicing sheet, and the stage. The plurality of protruding portions includes a plurality of first protruding portions and a plurality of second protruding portions different in height or vertical elastic modulus from each other.

### BACKGROUND OF THE INVENTION

### Field of the Invention

The present disclosure relates to manufacturing of semiconductor devices, and particularly relates to a pickup technique for picking up a diced semiconductor chip from a dicing sheet.

### Description of the Background Art

As one of apparatuses for manufacturing semiconductor devices, a pickup apparatus that picks up semiconductor chips diced on a dicing sheet from the dicing sheet is known. For example, Japanese Patent Application Laid-Open No. 2008-103493 below proposes a pickup apparatus in which a dicing sheet to which semiconductor chips are attached is vacuum-sucked to a stage provided with a plurality of protruding portions on a front surface, the semiconductor chips are made in a state of being point-bonded to the dicing sheet to be easily peeled off, and then the semiconductor chips are picked up from the dicing sheet.

In the technique of Japanese Patent Application Laid-Open No. 2008-103493, when the size of the semiconductor chip is large and the number of places where the semiconductor chips are point-bonded to the dicing sheet is extremely large, there arises a problem that the effect of making the semiconductor chips in a state of being easily peeled off from the dicing sheet cannot be sufficiently obtained. Therefore, when the size of the semiconductor chip is large, it is necessary to widen the interval between the protruding objects on the stage. On the other hand, when the size of the semiconductor chip is small and the number of places where the semiconductor chips are point-bonded to the dicing sheet is very small, there arises a problem that the semiconductor chips are peeled off and flown apart when the dicing sheet is vacuum-sucked to a stage provided with a plurality of protruding portions. Therefore, when the size of the semiconductor chip is small, it is necessary to reduce the interval between the protruding objects on the stage. Therefore, for example, when large-sized semiconductor chips and small-sized semiconductor chips are mixed in the semiconductor chips cut out from one semiconductor wafer, any one of the above two problems occurs.

### SUMMARY

An object of the present disclosure is to provide an apparatus for manufacturing a semiconductor device and a method of manufacturing a semiconductor device capable of picking up each semiconductor chip by appropriately making each semiconductor chip in a state of being easily peeled off from a dicing sheet even when semiconductor chips different in size are mixed.

An apparatus for manufacturing a semiconductor device according to the present disclosure includes: a stage including a plurality of protruding portions disposed so as to face a back surface of a dicing sheet to which a semiconductor chip is attached on a front surface; and a suction unit configured to vacuum-suck a space between the dicing sheet and the stage.

The plurality of protruding portions includes a plurality of first protruding portions and a plurality of second protruding portions different in height or vertical elastic modulus from each other.

Since a plurality of first protruding portions and a plurality of second protruding portions different in height or vertical elastic modulus from each other are provided on the stage, when the dicing sheet is vacuum-sucked to the stage, it is possible to prevent the number of places where the large-sized semiconductor chip is point-bonded to the dicing sheet from becoming very large, and it is possible to prevent the number of places where the small-sized semiconductor chip is point-bonded to the dicing sheet from becoming very small.

Therefore, even when the semiconductor chips different in size are mixed, each semiconductor chip can be picked up by making each semiconductor chip in a state of being appropriately easily peeled off from the dicing sheet.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram showing a configuration of a pickup apparatus according to a first preferred embodiment (a state before a stage is raised);

FIG. 2 is a diagram showing a configuration of a pickup apparatus according to the first preferred embodiment (a state after the stage is raised);

FIG. 3 is a partial cross-sectional view of the stage of the pickup apparatus according to the first preferred embodiment;

FIG. 4 is a partial plan view of the stage of the pickup apparatus according to the first preferred embodiment;

FIG. 5 is a diagram showing a state in which a dicing sheet to which a large-sized semiconductor chip is attached is sucked to the stage of the pickup apparatus according to the first preferred embodiment;

FIG. 6 is a diagram showing a state in which a dicing sheet to which a small-sized semiconductor chip is attached is sucked to the stage of the pickup apparatus according to the first preferred embodiment;

FIG. 7 is a diagram showing a configuration of a pickup apparatus according to a second preferred embodiment;

FIG. 8 is a diagram showing a configuration of a pickup apparatus according to a third preferred embodiment;

FIGS. 9 and 10 are diagrams each for illustrating an example of a region where a spring is provided in a protruding portion in the pickup apparatus according to the third preferred embodiment;

FIG. 11 is a partial plan view of the stage of a pickup apparatus according to a fourth preferred embodiment;

FIG. 12 is a partial plan view of the stage of a pickup apparatus according to a fifth preferred embodiment;

FIG. 13 is a partial cross-sectional view of the stage of a pickup apparatus according to a sixth preferred embodiment;

FIG. 14 is a schematic top view of the stage of a pickup apparatus according to a seventh preferred embodiment;

FIG. 15 is a partial plan view of the stage of the pickup apparatus according to the seventh preferred embodiment; and

FIG. 16 is a partial cross-sectional view of the stage of the pickup apparatus according to the seventh preferred embodiment.

### DESCRIPTION OF THE PREFERRED EMBODIMENTS

### First Preferred Embodiment

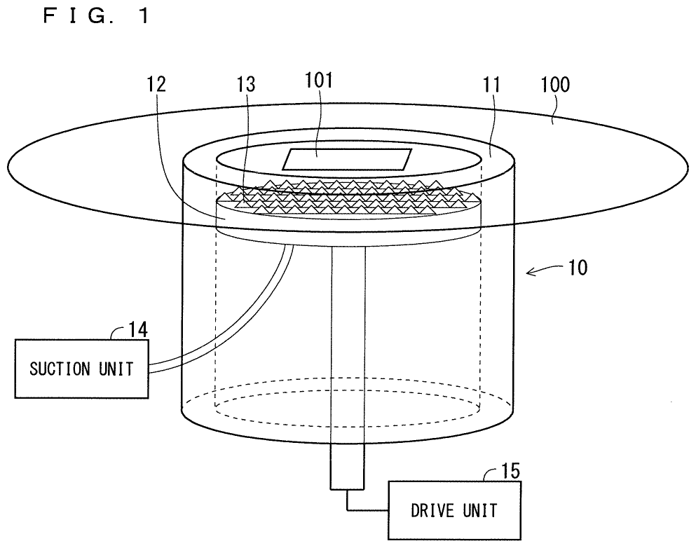

FIG. 1 is a diagram showing a configuration of a pickup apparatus 10 that is an apparatus for manufacturing semiconductor devices according to a first preferred embodiment. As shown in FIG. 1, the pickup apparatus 10 includes an outer frame 11, a stage 12 with a pin holder shape having a plurality of protruding portions 13 on a front surface thereof, a suction unit 14, and a drive unit 15.

A dicing sheet 100 to which semiconductor chips 101 are attached is fixed to the outer frame 11. The stage 12 is installed inside the outer frame 11, and the protruding portions 13 provided on the front surface thereof is disposed so as to face the back surface of the dicing sheet 100 fixed to the outer frame 11. The interval between the apexes of the plurality of protruding portions 13 is preferably 2 mm or less. It should be noted that the dicing sheet 100 may be directly fixed to the stage 12, and in this case, the apparatus for manufacturing semiconductor devices does not need to include the outer frame 11.

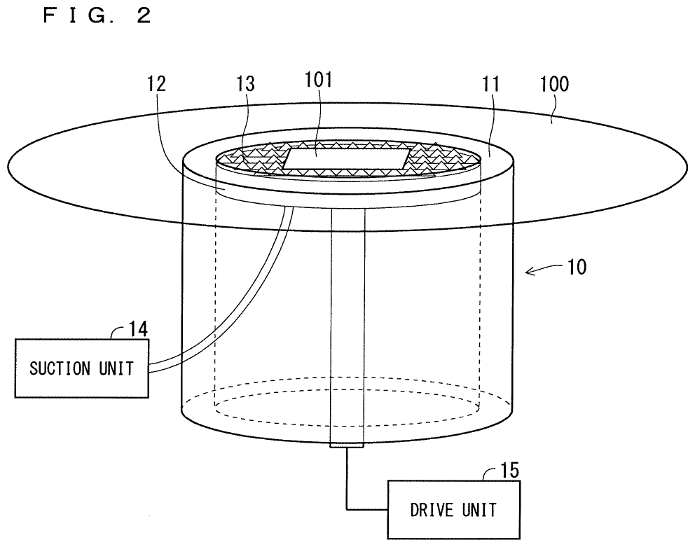

Suction grooves connected to the suction unit 14 through a tube are provided in trough portions between the protruding portions 13 in the stage 12. The suction unit 14 can suck the dicing sheet 100 to the protruding portions 13 of the stage 12 by performing vacuuming on spaces between the outer frame 11 and the dicing sheet 100, that is, spaces defined by the outer frame 11, the dicing sheet 100, and the stage 12 from the suction grooves. The drive unit 15 can raise and lower the protruding portions 13 by moving a supporting shaft supporting the stage 12 up and down. FIG. 2 shows a state in which the stage 12 is raised to the vicinity of the height of the dicing sheet 100. In addition, although not shown, the pickup apparatus 10 includes a pickup unit that picks up the semiconductor chips 101 from the dicing sheet 100. However, the pickup unit may be an apparatus different from the pickup apparatus 10. That is, the pickup apparatus 10 does not necessarily need to include the pickup unit.

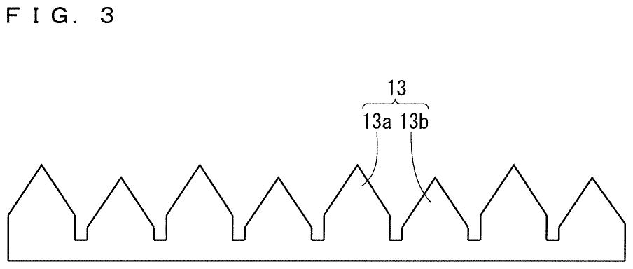

FIG. 3 is a partial cross-sectional view of the stage 12 of the pickup apparatus 10 according to the first preferred embodiment. As shown in FIG. 3, the plurality of protruding portions 13 provided on the stage 12 include a plurality of first protruding portions 13a and a plurality of second protruding portions 13b that are different in height from each other. Here, the height of the second protruding portion 13b is set to be lower than that of the first protruding portion 13a. The difference between the height of the first protruding portion 13a and the height of the second protruding portion 13b is preferably 1 mm or less, and more preferably 0.1 mm or more and 0.5 mm or less.

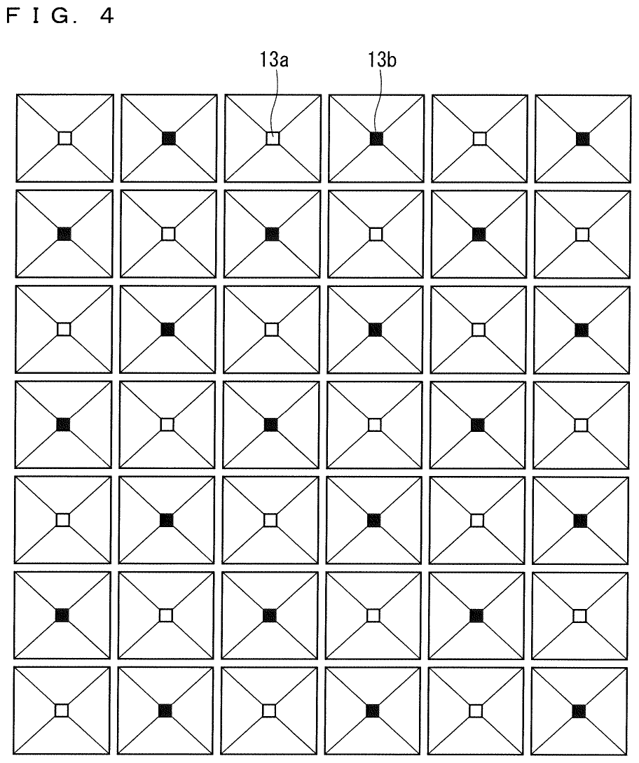

FIG. 4 is a partial plan view of the stage 12 of the pickup apparatus 10 according to the first preferred embodiment. To facilitate understanding, in FIG. 4, the apex of the first protruding portion 13a is black, and the apex of the second protruding portion 13b is white. In the present preferred embodiment, as shown in FIG. 4, the first protruding portions 13a and the second protruding portions 13b are alternately disposed on the upper surface of stage 12.

A method of manufacturing a semiconductor device using the pickup apparatus 10, particularly, a method of picking up a semiconductor chip 101 attached to the dicing sheet 100 will be described.

First, by fixing the dicing sheet 100 to the outer frame 11 of the pickup apparatus 10, the dicing sheet 100 is disposed on the stage 12. Then, a semiconductor wafer from which the semiconductor chip 101 is cut out is mounted on the dicing sheet 100 fixed to the outer frame 11. Thereafter, the semiconductor wafer mounted on the dicing sheet 100 is diced, and the semiconductor chip 101 is cut out from the semiconductor wafer.

Thereafter, the stage 12 is raised by the drive unit 15, and the apex of the protruding portion 13 on the stage 12 is brought into contact with the dicing sheet 100. Subsequently, the space defined by the outer frame 11, the dicing sheet 100, and the stage 12 is vacuumed by the suction unit 14, whereby the dicing sheet 100 is deformed along the protruding portion 13. Accordingly, the semiconductor chip 101 is in a state of being point-bonded to the dicing sheet 100 at the apex of the protruding portion 13 and being easily peeled off.

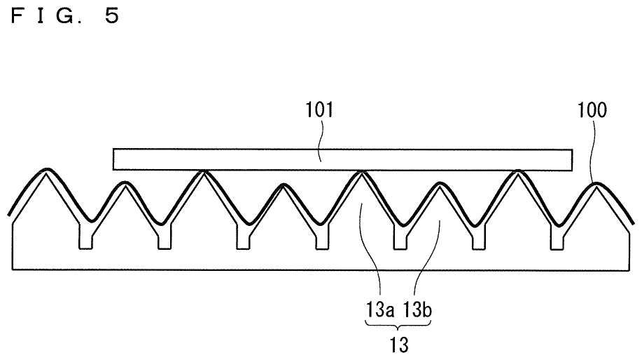

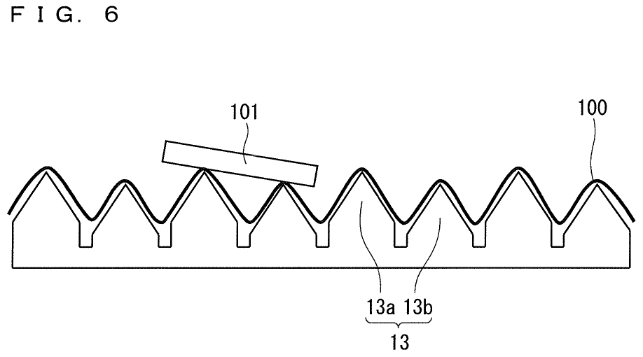

In the present preferred embodiment, on the stage 12, the first protruding portions 13a and the second protruding portions 13b lower than the first protruding portions 13a are alternately disposed as the protruding portions 13. Therefore, when the size of the semiconductor chip 101 is large, as shown in FIG. 5, the semiconductor chip 101 is in a state of being point-bonded to the dicing sheet 100 only at the apex of the first protruding portion 13a and being peeled off from the dicing sheet 100 above the second protruding portion 13b, and it is prevented that the number of places where the semiconductor chip 101 is point-bonded to the dicing sheet 100 is extremely large. In addition, when the size of the semiconductor chip 101 is small, as shown in FIG. 6, the semiconductor chip 101 is in a state of being point-bonded to the dicing sheet 100 at both of the apexes of the first protruding portion 13a and the second protruding portion 13b, and the semiconductor chip 101 is prevented from being peeled off and flying apart from the dicing sheet 100.

In this state, by picking up the semiconductor chip 101 from the dicing sheet 100 by a pickup unit (not shown), the semiconductor chip 101 can be easily picked up.

Before the step of deforming the dicing sheet 100 along the protruding portion 13, the semiconductor chip 101 may be irradiated with UV (ultraviolet) rays in a vacuum state. By irradiating the dicing sheet 100 with UV rays, the adhesive force of the dicing sheet 100 decreases, and when the dicing sheet 100 is deformed along the protruding portion 13, the dicing sheet 100 is easily peeled off from the semiconductor chip 101, and stress applied to the semiconductor chip 101 can be suppressed.

In addition, the pickup apparatus 10 may include a temperature adjustment unit capable of adjusting the temperature of the dicing sheet 100 fixed to the outer frame 11. Since when the temperature is increased, the dicing sheet 100 has elastic modulus decreased and is likely to be bent, by increasing the temperature of the dicing sheet 100 when the dicing sheet 100 is deformed along the protruding portion 13, the dicing sheet 100 is easily peeled off from the semiconductor chip 101, and stress applied to the semiconductor chip 101 can be suppressed.

As described above, according to the pickup apparatus 10 of the first preferred embodiment, since the first protruding portion 13a and the second protruding portion 13b different in height from each other are provided as the protruding portions 13 on the stage 12, when the dicing sheet 100 is vacuum-sucked to the stage 12, it is possible to prevent the number of places where the large-sized semiconductor chip 101 is point-bonded to the dicing sheet 100 from becoming very large, and it is possible to prevent the number of places where the small-sized semiconductor chip 101 is point-bonded to the dicing sheet 100 from becoming very small. Therefore, even when the semiconductor chips 101 different in size are mixed, each semiconductor chip 101 can be picked up in a state of being appropriately easily peeled off from the dicing sheet 100.

It should be noted that the protruding portions 13 may be individually detachable from the stage 12. In this case, since the height and shape (such as the angle of the point of the apex) of each of the protruding portions 13, the distance between the apexes, the installed number of protruding portions 13, and the like can be optionally changed, the optimal arrangement and height of the protruding portions 13 can be achieved according to the size of the semiconductor chip 101, the adhesive force of the dicing sheet 100, and the like.

### Second Preferred Embodiment

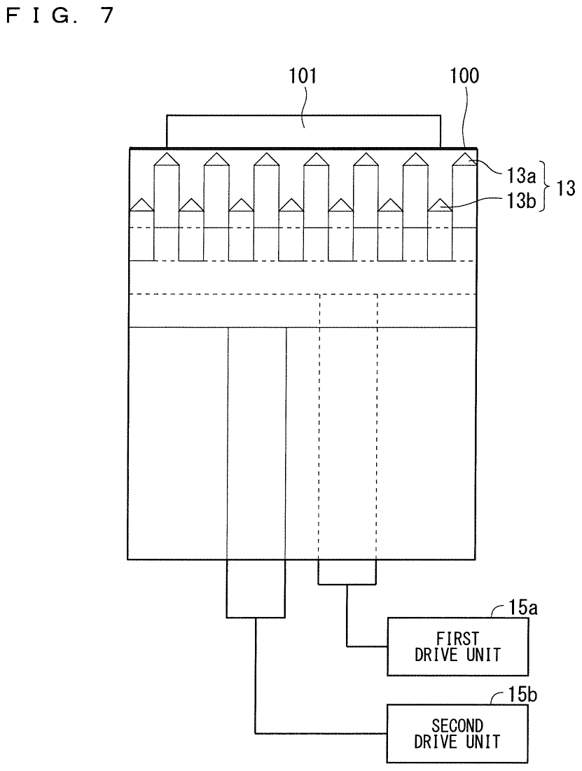

FIG. 7 is a diagram showing a configuration of a pickup apparatus 10 according to a second preferred embodiment. In the pickup apparatus 10 according to the second preferred embodiment, the stage 12 is two-axis controlled so that the portion of the first protruding portion 13a and the portion of the second protruding portion 13b can be raised and lowered independently of each other. That is, the pickup apparatus 10 according to the second preferred embodiment includes, as the drive unit 15, a first drive unit 15a that raises and lowers first protruding portion 13a and a second drive unit 15b that raises and lowers the second protruding portion 13b, and the first protruding portion 13a and the second protruding portion 13b can be raised and lowered independently of each other.

According to the pickup apparatus 10 of the second preferred embodiment, since each of the height of the first protruding portion 13a and the height of the second protruding portion 13b can be controlled, the heights of the first protruding portion 13a and the second protruding portion 13b and the difference between the heights thereof can be adjusted according to the size of the semiconductor chip 101, the adhesive force of the dicing sheet 100, and the like.

Also in the present preferred embodiment, the protruding portions 13 may be individually detachable from the stage 12.

### Third Preferred Embodiment

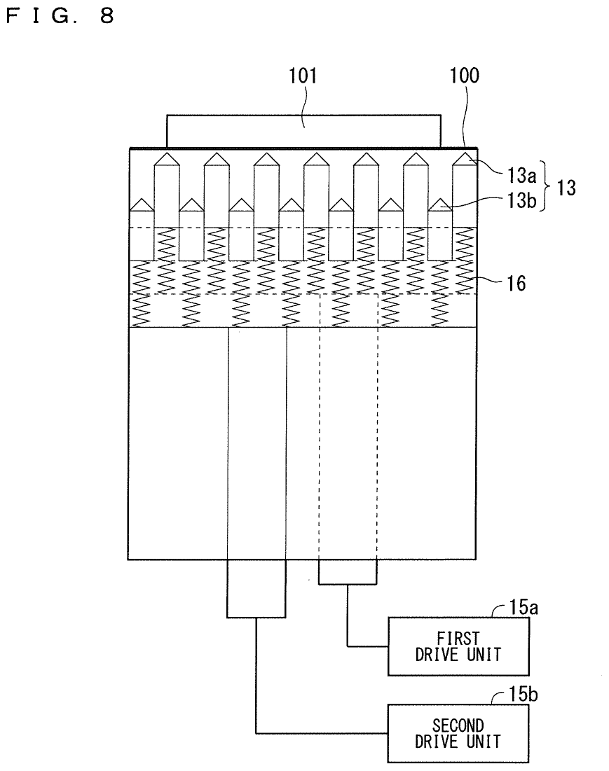

FIG. 8 is a diagram showing a configuration of a pickup apparatus 10 according to a third preferred embodiment. In the pickup apparatus 10 according to the third preferred embodiment, into at least some of the plurality of protruding portions 13, a spring 16 that causes the protruding portion 13 to have elasticity in the vertical direction is inserted.

The apex of the protruding portion 13 having the spring 16 is lowered as the suction of the dicing sheet 100 to the stage 12 proceeds. Therefore, in the present preferred embodiment, the peeling-off of the dicing sheet 100 from the semiconductor chip 101 can proceed preferentially from the portion of the protruding portion 13 having the spring 16.

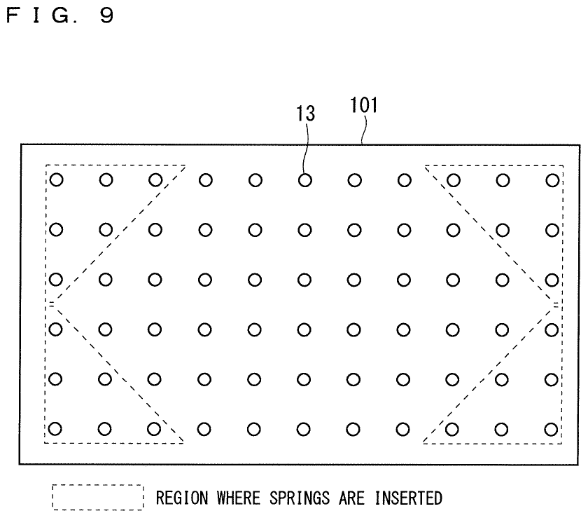

For example, as shown in FIG. 9, by providing the spring 16 in the protruding portion 13 disposed in the region corresponding to the outer peripheral portion of the semiconductor chip 101 stuck to the dicing sheet 100 fixed to the outer frame 11, the peeling-off of the dicing sheet 100 proceeds inward from the outer peripheral portion of the semiconductor chip 101, and the adhesive of the dicing sheet 100 can be suppressed from remaining in the semiconductor chip 101.

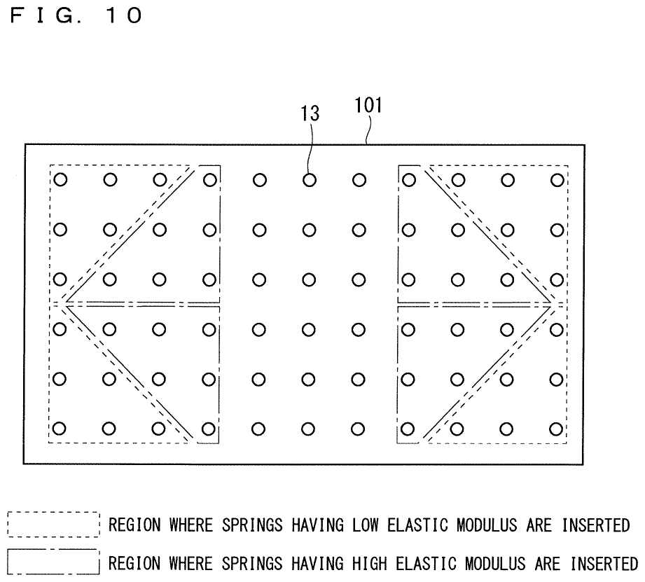

Furthermore, as shown in FIG. 10, a spring having a relatively low elastic modulus (likely to be deformed) may be provided in the protruding portion 13 disposed at a position close to the outer peripheral portion of the semiconductor chip 101 stuck to the dicing sheet 100 fixed to the outer frame 11, and a spring having a relatively high elastic modulus (less likely to be deformed) may be provided in the protruding portion 13 disposed at a position close to the central portion of the semiconductor chip 101. With this, the peeling-off of the dicing sheet 100 proceeds more smoothly inward from the outer peripheral portion of the semiconductor chip 101.

Also in the present preferred embodiment, the protruding portions 13 may be individually detachable from the stage 12. In addition, the springs 16 may also be made individually detachable, and the position of the protruding portion 13 having the spring 16 may be made changeable.

### Fourth Preferred Embodiment

FIG. 4 shows an example in which the first protruding portion 13a and the second protruding portion 13b are alternately arranged on the upper surface of the stage 12. However, the first protruding portion 13a and the second protruding portion 13b do not need to be alternately arranged.

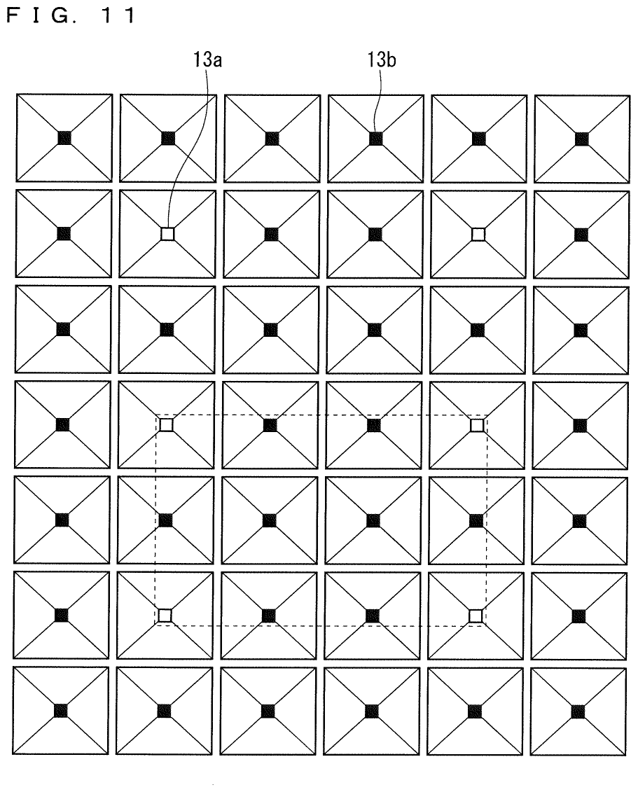

FIG. 11 shows an example in which the first protruding portions 13a and the second protruding portions 13b are not alternately arranged. In FIG. 11, in a plan view, in the longitudinal direction, first protruding portions 13a and second protruding portions 13b are alternately arranged, but in the lateral direction, two second protruding portions 13b are arranged between one first protruding portion 13a and next first protruding portion 13a. That is, the apexes of four first protruding portions 13a adjacent to each other are arranged to form vertices of a rectangle (dotted line shown in FIG. 11) in a plan view.

As described above, when the apexes of four first protruding portions 13a adjacent to each other are arranged to form four vertices of a rectangle, the arrangement is preferably made so that the length of a diagonal line of the rectangle is 4 mm or less (more preferably when 0.5 mm or more and 2.5 mm or less).

By providing a degree of freedom in arrangement without limiting the arrangement of the first protruding portion 13a and the second protruding portion 13b to alternation, it is possible to optimize the arrangement of the protruding portion 13 with respect to the shape of the semiconductor chip 101. That is, the first protruding portion 13a can be disposed at a position suitable for supporting the semiconductor chip 101.

### Fifth Preferred Embodiment

Although FIGS. 4 and 11 show an example in which the protruding portions 13 (the first protruding portions 13a and the second protruding portions 13b) are laid in a grid pattern on the upper surface of the stage 12, the stage 12 may include some portions on which the protruding portion 13 is not disposed.

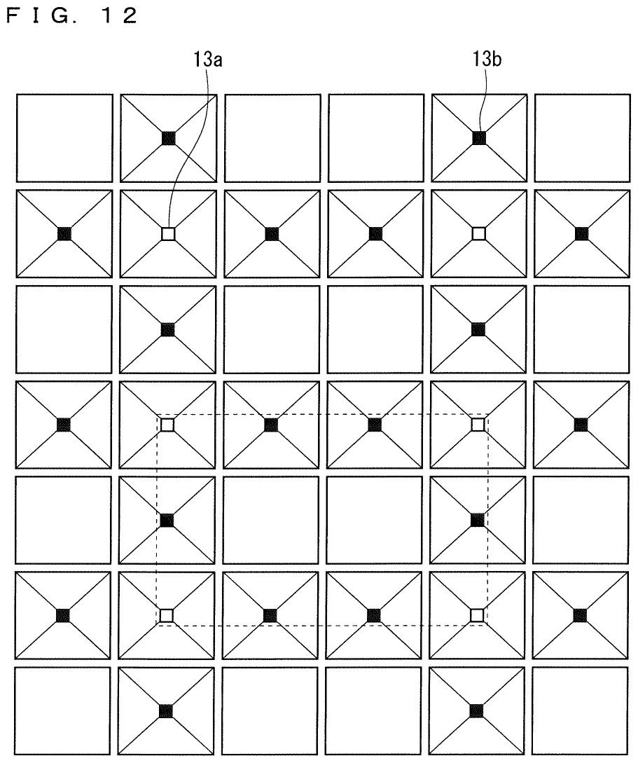

FIG. 12 shows an example in which there are some portions on which the protruding portions 13 are not disposed. The arrangement in FIG. 12 is obtained by removing the second protruding portion 13b not adjacent to the first protruding portion 13a from the arrangement in FIG. 11. In other words, in a plan view, the second protruding portions 13b are disposed only in regions vertically and horizontally adjacent to the regions where the first protruding portions 13a are disposed, and neither first protruding portions 13a nor second protruding portions 13b are disposed in other regions.

As described above, by allowing a region where the protruding portion 13 is not arranged to remain on the upper surface of the stage 12, the arrangement of the protruding portion 13 with respect to the shape of the semiconductor chip 101 can be optimized. That is, it is possible not to dispose the protruding portion 13 at a position unnecessary for supporting the semiconductor chip 101.

Also in the present preferred embodiment, when the apexes of four first protruding portions 13a adjacent to each other are arranged to form vertices of a rectangle (dotted line shown in FIG. 12), the arrangement is preferably made so that the length of a diagonal line of the rectangle is 4 mm or less (more preferably when 0.5 mm or more and 2.5 mm or less).

### Sixth Preferred Embodiment

In the first to fifth preferred embodiments, the first protruding portion 13a and the second protruding portion 13b provided on the stage 12 have different heights. On the other hand, in a sixth preferred embodiment, the first protruding portion 13a and the second protruding portion 13b have different elastic moduli in the vertical direction.

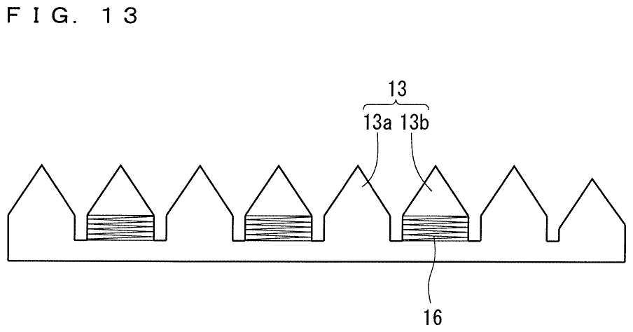

FIG. 13 is a partial cross-sectional view of the stage 12 of the pickup apparatus 10 according to the sixth preferred embodiment. As shown in FIG. 13, a plurality of protruding portions 13 provided on the stage 12 include a first protruding portion 13a having no spring 16 and a second protruding portion 13b having a spring 16. Since the spring 16 acts on the second protruding portion 13b to have elasticity in the vertical direction, the elastic modulus in the vertical direction of the second protruding portion 13b is lower than that of the first protruding portion 13a.

The present preferred embodiment is similar to the first to fifth preferred embodiments except that a second protruding portion 13b having a spring 16 is used instead of the second protruding portion 13b having a low height. It should be noted that the first protruding portion 13a having no spring 16 and the second protruding portion 13b having the spring 16 may have the same height.

In the step of vacuum-sucking the space defined by the outer frame 11, the dicing sheet 100, and the stage 12 to deform the dicing sheet 100 along the protruding portion 13, since the second protruding portion 13b having the spring 16 contracts and becomes low, the second protruding portion 13b acts as with the second protruding portion 13b of the first preferred embodiment. Therefore, also in the sixth preferred embodiment, the same effects as those of the first preferred embodiment can be obtained.

In addition, since the second protruding portion 13b of the sixth preferred embodiment has elasticity in the vertical direction, the second protruding portion 13b is gradually lowered when the dicing sheet 100 is deformed along the protruding portion 13. Therefore, as compared with the case in the first preferred embodiment, the dicing sheet 100 can be gently deformed, and the semiconductor chip 101 is prevented from being damaged or unintentionally peeled off by the impact when the dicing sheet 100 is deformed.

### Seventh Preferred Embodiment

In the description of the seventh preferred embodiment, the “first protruding portion 13a” refers to the first protruding portion 13a having a high height of the first preferred embodiment, or the first protruding portion 13a not including the spring 16 of the sixth preferred embodiment, and the “second protruding portion 13b” refers to the second protruding portion 13b having a low height of the first preferred embodiment, or the second protruding portion 13b including the spring 16 of the sixth preferred embodiment.

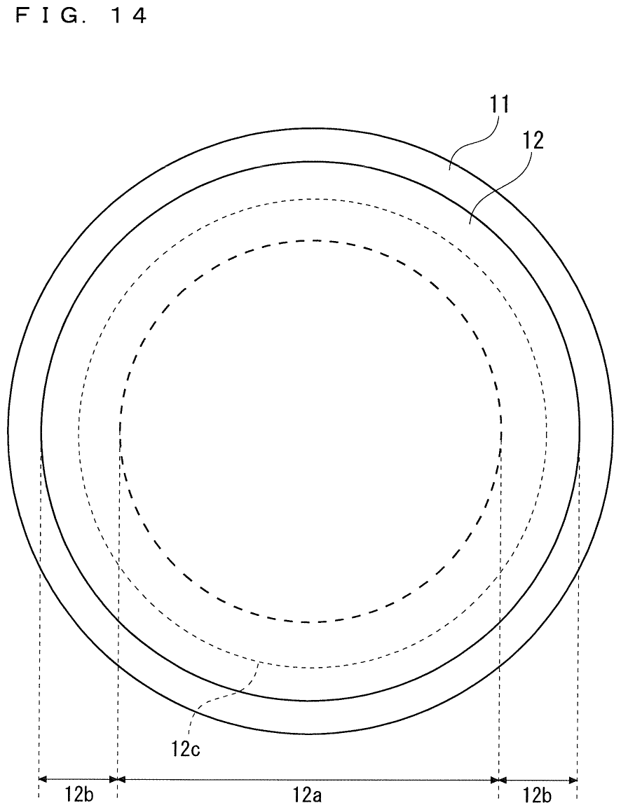

FIG. 14 is a schematic top view of the stage 12 of the pickup apparatus 10 according to the seventh preferred embodiment. As shown in FIG. 14, the upper surface of the stage 12 is divided into a central portion 12a and an outer peripheral portion 12b outside the central portion. Here, the central portion 12a of the stage 12 is included in a wafer placement region 12c being a region on which the semiconductor wafer before the semiconductor chip 101 is cutout is placed. Therefore, the outer edge portion of the wafer placement region 12c is positioned in the outer peripheral portion 12b of the stage 12.

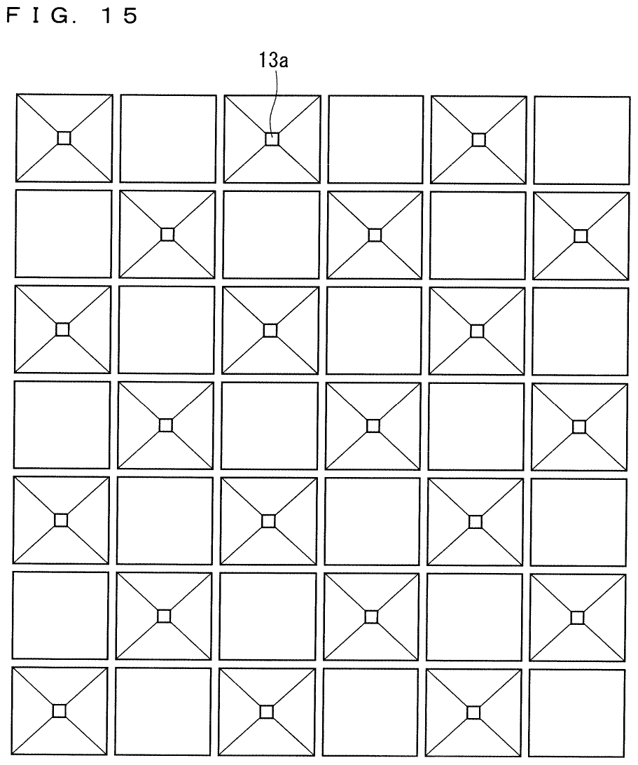

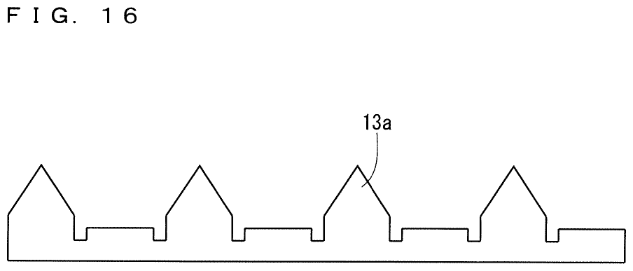

In the present preferred embodiment, the second protruding portion 13b is not disposed in the central portion 12a of the stage 12, but is disposed only in the outer peripheral portion 12b. That is, as in the partial plan view shown in FIG. 15 and the partial cross-sectional view shown in FIG. 16, only the first protruding portion 13a is disposed in the central portion 12a, and both the first protruding portion 13a and the second protruding portion 13b are disposed in the outer peripheral portion 12b as in the first to fifth preferred embodiments.

On an outer peripheral portion of the semiconductor wafer placed on the stage 12, cut ends of small pieces are generated by dicing. When the cut ends are unintentionally peeled off from the semiconductor chip 101 and flown apart, a problem occurs in which the cut ends adhere onto the semiconductor chip 101 that is to be a product. As in the present preferred embodiment, by disposing the second protruding portion 13b in the outer peripheral portion 12b of the stage 12, it is possible to suppress flying-apart of the cut ends in the outer peripheral portion of the semiconductor wafer.

It should be noted that each preferred embodiment can be freely combined, and each preferred embodiment can be appropriately modified or omitted.

### APPENDIX

Hereinafter, various aspects of the present disclosure will be collectively described as appendixes.

### APPENDIX 1

An apparatus for manufacturing a semiconductor device, the apparatus comprising:
a stage including a plurality of protruding portions disposed so as to face a back surface of a dicing sheet to which a semiconductor chip is attached on a front surface; and
a suction unit configured to vacuum-suck a space between the dicing sheet and the stage,
wherein the plurality of protruding portions includes a plurality of first protruding portions and a plurality of second protruding portions different in height or vertical elastic modulus from each other.

### APPENDIX 2

The apparatus for manufacturing a semiconductor device according to appendix 1,
wherein each of the first protruding portions and each of the second protruding portions are different in height from each other, and
wherein a difference between a height of the first protruding portion and a height of the second protruding portion is 1 mm or less.

### APPENDIX 3

The apparatus for manufacturing a semiconductor device according to appendix 1,
wherein each of the first protruding portions and each of the second protruding portions are different in vertical elastic modulus from each other,
wherein the second protruding portion includes a spring configured to provide vertical elasticity, and
wherein the first protruding portion does not include the spring.

### APPENDIX 4

The apparatus for manufacturing a semiconductor device according to any one of appendixes 1 to 3, wherein an interval between apexes of the plurality of protruding portions is 2 mm or less.

### APPENDIX 5

The apparatus for manufacturing a semiconductor device according to any one of appendixes 1 to 4, wherein the first protruding portions and the second protruding portions are alternately arranged.

### APPENDIX 6

The apparatus for manufacturing a semiconductor device according to any one of appendixes 1 to 3, wherein the plurality of first protruding portions is arranged so that apexes of four of the first protruding portions adjacent to each other form vertices of a rectangle having a diagonal length of 4 mm or less.

### APPENDIX 7

The apparatus for manufacturing a semiconductor device according to any one of appendixes 1 to 6, wherein the stage includes some portions on which the protruding portion is not disposed.

### APPENDIX 8

The apparatus for manufacturing a semiconductor device according to any one of appendixes 1 to 7,
wherein each of the second protruding portions is lower in height or lower in vertical elastic modulus than each of the first protruding portions, and
wherein only the first protruding portions are disposed in a central portion of the stage, and both the first protruding portions and the second protruding portions are disposed in an outer peripheral portion of the stage.

### APPENDIX 9

The apparatus for manufacturing a semiconductor device according to any one of appendixes 1 to 8, wherein the protruding portions are individually detachable from the stage.

### APPENDIX 10

The apparatus for manufacturing a semiconductor device according to any one of appendixes 1 to 9, further comprising a drive unit configured to raise and lower the plurality of protruding portions.

### APPENDIX 11

The apparatus for manufacturing a semiconductor device according to appendix 10, wherein the drive unit includes a first drive unit that raises and lowers the plurality of first protruding portions and a second drive unit that raises and lowers the plurality of second protruding portions, and the drive unit raises and lowers the plurality of first protruding portions and the plurality of second protruding portions independently of each other.

### APPENDIX 12

The apparatus for manufacturing a semiconductor device according to appendix 1 or 2, wherein at least some of the plurality of protruding portions includes springs that cause the protruding portions to have vertical elasticity.

### APPENDIX 13

The apparatus for manufacturing a semiconductor device according to appendix 12, wherein the springs are provided at least in the protruding portions disposed in a region corresponding to an outer peripheral portion of the semiconductor chip stuck to the dicing sheet.

### APPENDIX 14

The apparatus for manufacturing a semiconductor device according to appendix 12, wherein an elastic modulus of the springs provided in the protruding portions disposed in a region close to a central portion of the semiconductor chip stuck to the dicing sheet is higher than an elastic modulus of the springs provided in the protruding portions disposed in a region close to an outer peripheral portion of the semiconductor chip.

### APPENDIX 15

The apparatus for manufacturing a semiconductor device according to any one of appendixes 1 to 14, further comprising a temperature adjustment unit configured to adjust a temperature of the dicing sheet.

### APPENDIX 16

The apparatus for manufacturing a semiconductor device according to any one of appendixes 1 to 15, further comprising a pickup unit configured to pick up the semiconductor chip from the dicing sheet.

### APPENDIX 17

A method of manufacturing a semiconductor device, the method comprising the steps of:
arranging the dicing sheet on the stage of the apparatus for manufacturing a semiconductor device according to any one of appendixes 1 to 16;
mounting a semiconductor wafer on the dicing sheet;
dicing the mounted semiconductor wafer to cut out the semiconductor chip;
after the step of cutting out the semiconductor chip, deforming the dicing sheet along the protruding portions by vacuum-sucking a space between the dicing sheet and the stage by the suction unit; and
after the step of deforming the dicing sheet, picking up the semiconductor chip from the dicing sheet.

### APPENDIX 18

The method of manufacturing a semiconductor device according to appendix 17, further comprising before the step of deforming the dicing sheet along the protruding portions, irradiating the semiconductor chip with ultraviolet rays in a vacuum state.

While the disclosure has been shown and described in detail, the foregoing description is in all aspects illustrative and not restrictive. It is therefore understood that numerous modifications and variations can be devised.

What is claimed is:

1. An apparatus for manufacturing a semiconductor device, the apparatus comprising:
a stage including a plurality of protruding portions disposed so as to face a back surface of a dicing sheet to which a semiconductor chip is attached on a front surface; and
a suction unit configured to vacuum-suck a space between the dicing sheet and the stage,
wherein the plurality of protruding portions includes a plurality of first protruding portions and a plurality of second protruding portions different in height or vertical elastic modulus from each other.

2. The apparatus for manufacturing a semiconductor device according to claim 1,
wherein each of the first protruding portions and each of the second protruding portions are different in height from each other, and
wherein a difference between a height of the first protruding portion and a height of the second protruding portion is 1 mm or less.

3. The apparatus for manufacturing a semiconductor device according to claim 1,
wherein each of the first protruding portions and each of the second protruding portions are different in vertical elastic modulus from each other,
wherein the second protruding portion includes a spring configured to provide vertical elasticity, and
wherein the first protruding portion does not include the spring.

4. The apparatus for manufacturing a semiconductor device according to claim 1, wherein an interval between apexes of the plurality of protruding portions is 2 mm or less.

5. The apparatus for manufacturing a semiconductor device according to claim 1, wherein the first protruding portions and the second protruding portions are alternately arranged.

6. The apparatus for manufacturing a semiconductor device according to claim 1, wherein the plurality of first protruding portions is arranged so that apexes of four of the first protruding portions adjacent to each other form vertices of a rectangle having a diagonal length of 4 mm or less.

7. The apparatus for manufacturing a semiconductor device according to claim 1, wherein the stage includes some portions on which the protruding portion is not disposed.

8. The apparatus for manufacturing a semiconductor device according to claim 1,
wherein each of the second protruding portions is lower in height or lower in vertical elastic modulus than each of the first protruding portions, and
wherein only the first protruding portions are disposed in a central portion of the stage, and both the first protruding portions and the second protruding portions are disposed in an outer peripheral portion of the stage.

9. The apparatus for manufacturing a semiconductor device according to claim 1, wherein the protruding portions are individually detachable from the stage.

10. The apparatus for manufacturing a semiconductor device according to claim 1, further comprising a drive unit configured to raise and lower the plurality of protruding portions.

11. The apparatus for manufacturing a semiconductor device according to claim 10, wherein the drive unit includes a first drive unit that raises and lowers the plurality of first protruding portions and a second drive unit that raises and lowers the plurality of second protruding portions, and the drive unit raises and lowers the plurality of first protruding portions and the plurality of second protruding portions independently of each other.

12. The apparatus for manufacturing a semiconductor device according to claim 1, wherein at least some of the plurality of protruding portions includes springs that cause the protruding portions to have vertical elasticity.

13. The apparatus for manufacturing a semiconductor device according to claim 12, wherein the springs are provided at least in the protruding portions disposed in a region corresponding to an outer peripheral portion of the semiconductor chip stuck to the dicing sheet.

14. The apparatus for manufacturing a semiconductor device according to claim 12, wherein an elastic modulus of the springs provided in the protruding portions disposed in a region close to a central portion of the semiconductor chip stuck to the dicing sheet is higher than an elastic modulus of the springs provided in the protruding portions disposed in a region close to an outer peripheral portion of the semiconductor chip.

15. The apparatus for manufacturing a semiconductor device according to claim 1, further comprising a temperature adjustment unit configured to adjust a temperature of the dicing sheet.

16. The apparatus for manufacturing a semiconductor device according to claim 1, further comprising a pickup unit configured to pick up the semiconductor chip from the dicing sheet.

17. A method of manufacturing a semiconductor device, the method comprising:
arranging the dicing sheet on the stage of the apparatus for manufacturing a semiconductor device according to claim 1;
mounting a semiconductor wafer on the dicing sheet;
dicing the mounted semiconductor wafer to cut out the semiconductor chip;
after cutting out the semiconductor chip, deforming the dicing sheet along the protruding portions by vacuum-sucking a space between the dicing sheet and the stage by the suction unit; and
after deforming the dicing sheet, picking up the semiconductor chip from the dicing sheet.

18. The method of manufacturing a semiconductor device according to claim 17, further comprising before deforming the dicing sheet along the protruding portions, irradiating the semiconductor chip with ultraviolet rays in a vacuum state.
